(19) United States
(12) Patent Application Publication
(10) Pub. No.: US 2006/0138412 A1
(43) Pub. Date: Jun. 29, 2006

(54) CMOS image sensor and fabricating method thereof

(76) Inventor: Se Jin Park, Gyeonggido (KR)

Correspondence Address: MCKENNA LONG & ALDRIDGE LLP;Song K. Jung, 1900 K Street, N.W., Washington, DC, 20006, US

(21) Appl. No.: 11/312,355

(22) Filed: Dec. 21, 2005

(30) Foreign Application Priority Data
Dec. 29, 2004 (KR) P 2004-0114848

(51) Int. Cl. H01L 31/0376; H01L 29/94

(52) U.S. Cl. 257/53; 257/369

(57) ABSTRACT

A CMOS image sensor and fabricating method thereof are provided, in which a microlens is additionally formed on a planarizing layer prior to a color filter forming step and by which transmission efficiency of light incident on a photodiode enhances performance of the image sensor. The CMOS image sensor includes a plurality of photodiodes on a semiconductor substrate to be uniformly spaced apart from each other, an insulating interlayer on the semiconductor substrate including the photodiodes, a protective layer on the insulating interlayer, a plurality of first microlenses on the protective layer to correspond to the photodiodes, respectively, a first planarizing layer over the substrate including the first microlenses, a color filter layer on the first planarizing layer, a second planarizing layer over the substrate including the color filter layer, and a plurality of second microlenses on the second planarizing layer to correspond to the first microlenses, respectively.

This application claims the benefit of Korean Patent Application No. 10-2004-0114848, filed on Dec. 29, 2004, which is hereby incorporated by reference for all purposes as if fully set forth herein.

### BACKGROUND OF THE INVENTION

1. Field of the Invention

The present invention relates to an image sensor, and more particularly, to a CMOS image sensor and fabricating method thereof. Although the present invention is suitable for a wide scope of applications, it is particularly suitable for suppressing a loss of light incident on a photodiode, simplifying a process and raising light transmission efficiency.

2. Discussion of the Related Art

An image sensor is a semiconductor device that converts an optical image to an electric signal and can be classified into a charge-coupled device and a complementary metal-oxide-semiconductor (CMOS) image sensor.

The CMOS image sensor includes a photodiode unit sensing an applied light and a CMOS logic circuit unit processing the sensed light into an electric signal as data. Photosensitivity of the image sensor is enhanced if a quantity of light received by the photodiode is raised. To enhance the photosensitivity, a fill factor, which is a photodiode area over entire area of image sensor, is raised to condense the diverted light to the photodiode. Alternatively, a path of light incident on an area except the photodiode is diverted to condense the diverted light to the photodiode.

For example, a microlens is used in condensing the diverted light to the photodiode. By providing a convex microlens formed of a material having good light transmittance over a photodiode, a path of incident light is refracted. Hence, more light can be applied to the photodiode area. In doing so, a light parallel to an optical axis of the microlens is refracted by the microlens to form a focus at a prescribed position on the optical axis.

Referring to FIG. 1, a CMOS image sensor according to a related art comprises one or more photodiodes 11 formed on a semiconductor substrate (not shown) to generate electric charges according to a quantity of an incident light. The CMOS image sensor further comprises an insulating interlayer 12 formed over the substrate including the photodiodes 11, a protective layer 13 formed on the insulating interlayer 12, a first planarizing layer 14 formed on the protective layer 13, an RGB color filter layer 15 formed on the first planarizing layer 14 to transmit light having a specific wavelength, a second planarizing layer 16 formed over the substrate including the color filter layer 15, and a microlens 17 formed on the second planarizing layer 16 to have a convex shape having a predetermined curvature and to condense the light to the corresponding photodiode 11 through the color filter layer 15.

An optical shielding layer (not shown) is provided within the insulating interlayer 12 to prevent the light from entering another area except the photodiode 11. The photodiode can be replaced by a photo gate to sense the light.

In the related art, a curvature, height and the like of the microlens 17 are determined by considering various factors including a focus of the condensed light. The microlens 17 is mainly formed of a polymer-based resin by deposition, patterning, reflowing, etc. Namely, the microlens 17 is formed to have a size, position and shape of a unit pixel, a thickness of the photosensitive device, an optimal size determined according to a height, position, size and the like of the optical shielding layer, and the radius of curvature.

The curvature, height and the like of the microlens 17 are determined by considering the various factors including the focus of the condensed light. The microlens 17 is formed of a photoresist by coating the photoresist, forming a photoresist pattern by performing exposure and development to pattern the photoresist, and performing reflowing on the photoresist pattern.

A shape of pattern profile depends on an exposure condition, e.g., focus, of the photoresist. For instance, a process condition is varied according to a situation of a sub-layer, whereby a profile of the microlens is changed as well. Thus, in the process for fabricating the related art CMOS image sensor, the microlens 17, provided to enhance a light-condensing power, is an important factor affecting characteristics of the image sensor. Thus, the microlens 17 may transmit more light to the photodiode 11 through the corresponding color filter layer 15 according to wavelength. That is, the light incident on the image sensor is condensed by the microlens 17, is filtered by the color filter layer 15, and then enters the photodiode 11 under the color filter layer 15. Therefore, the optical shielding layer plays a role in preventing the incident light from deviating to another light path.

In fabricating the related art CMOS image sensor, the color filter and microlens are formed by forming the first and second planarizing layers 14 and 16 and forming the color filter layer 15 and the microlens 17 over the first and second planarizing layers 14 and 16, respectively. However, the light transmission rate is reduced to degrade the performance of the CMOS image sensor.

### SUMMARY OF THE INVENTION

Accordingly, the present invention is directed to a CMOS image sensor and fabricating method thereof that substantially obviates one or more problems due to limitations and disadvantages of the related art.

An advantage of the present invention is to provide a CMOS image sensor and fabricating method thereof, in which a microlens is additionally formed on a planarizing layer prior to a color filter forming step, thereby enhancing performance of the image sensor as transmission efficiency of light incident on a photodiode is increased.

Additional features and advantages of the invention will be set forth in the description which follows, and in part will be apparent from the description, or may be learned by practice of the invention. The objectives and other advantages of the invention will be realized and attained by the structure and method particularly pointed out in the written description and claims hereof as well as the appended drawings.

To achieve these and other advantages and in accordance with the purpose of the invention, as embodied and broadly described, there is provided a CMOS image sensor including a plurality of photodiodes on a semiconductor substrate to be uniformly spaced apart from each other; an insulating interlayer on the semiconductor substrate including the photodiodes; a protective layer on the insulating interlayer; a plurality of first microlenses on the protective layer to correspond to the plurality of photodiodes, respectively; a first planarizing layer over the substrate including the first microlenses; a color filter layer on the first planarizing layer; a second planarizing layer over the substrate including the color filter layer; and a plurality of second microlenses on the second planarizing layer to correspond to the plurality of first microlenses, respectively.

In another aspect of the present invention, there is provided a method of fabricating a CMOS image sensor, the method comprising forming a plurality of photodiodes on a semiconductor substrate; forming an insulating interlayer on the semiconductor substrate including the photodiodes; forming a protective layer on the insulating interlayer; forming a plurality of first microlenses on the protective layer to correspond to the plurality of photodiodes, respectively; forming a first planarizing layer over the substrate including the first microlenses; forming a color filter layer on the first planarizing layer; forming a second planarizing layer over the substrate including the color filter layer; and forming a plurality of second microlenses on the second planarizing layer to correspond to the plurality of first microlenses, respectively.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiment(s) of the invention and together with the description serve to explain the principle of the invention. In the drawings:

FIG. 1 is a cross-sectional diagram of a CMOS image sensor according to a related art;

FIG. 2 is a cross-sectional diagram of a CMOS image sensor according to the present invention; and

FIGS. 3A-3E are cross-sectional diagrams of a method of fabricating a CMOS image sensor according to the present invention.

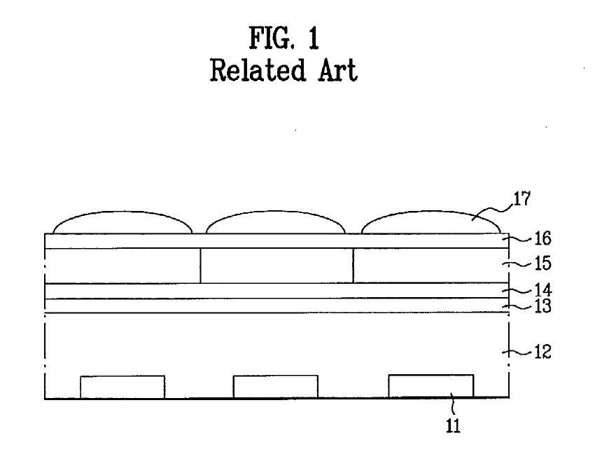

### DETAILED DESCRIPTION OF THE INVENTION

Reference will now be made in detail to the embodiments of the present invention, examples of which are illustrated in the accompanying drawings. Wherever possible, like reference designations will be used throughout the drawings to refer to the same or similar parts.

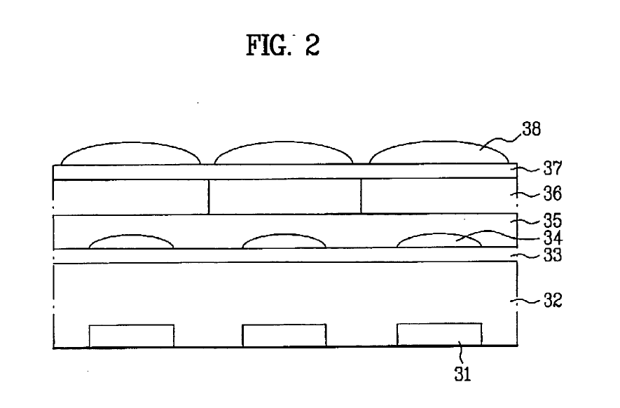

Referring to FIG. 2, a CMOS image sensor according to the present invention includes at least one photodiode 31 formed on a semiconductor substrate (not shown) to generate electric charges according to the intensity of radiation of an incident light. The CMOS image sensor further comprises an insulating interlayer 32 formed on the semiconductor substrate including the at least one photodiode 31, a protective layer 33 formed on the insulating interlayer 32, at least one first microlens 34 formed on the protective layer 33 to correspond to the at least one photodiode 31, a first planarizing layer 35 formed over the substrate including the at least one first microlens 34, a color filter layer 36 formed on the first planarizing layer 35 to correspond to the at least one first microlens 34, a second planarizing layer 37 formed over the substrate including the color filter layer 36, and at least one second microlens 38 formed on the second planarizing layer 37 to correspond to the color filter layer 36.

In the present invention, the protective layer 33 includes an oxide layer and a nitride layer stacked on the oxide layer. The second microlens 38 is overlapped with the first microlens 34 to have a width and curvature radius greater than those of the first microlens 34, respectively.

The first microlens 34 is formed of a material having a refractive index different from that of the second microlens 38. The refractive index of the second microlens 38 is greater than that of the first microlens 34.

Moreover, each of the first and second microlenses 34 and 38 is hemispherical.

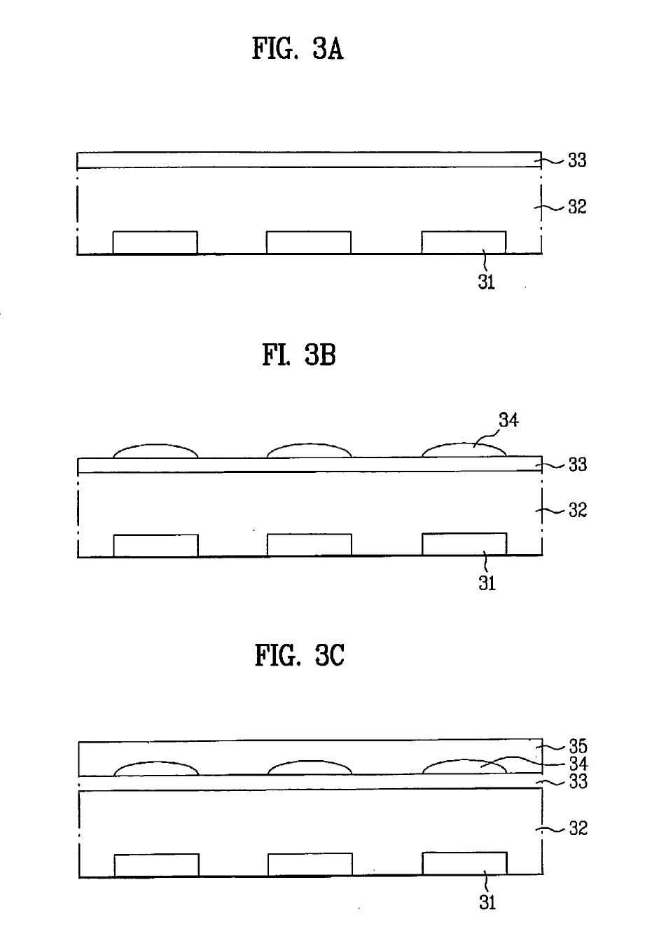

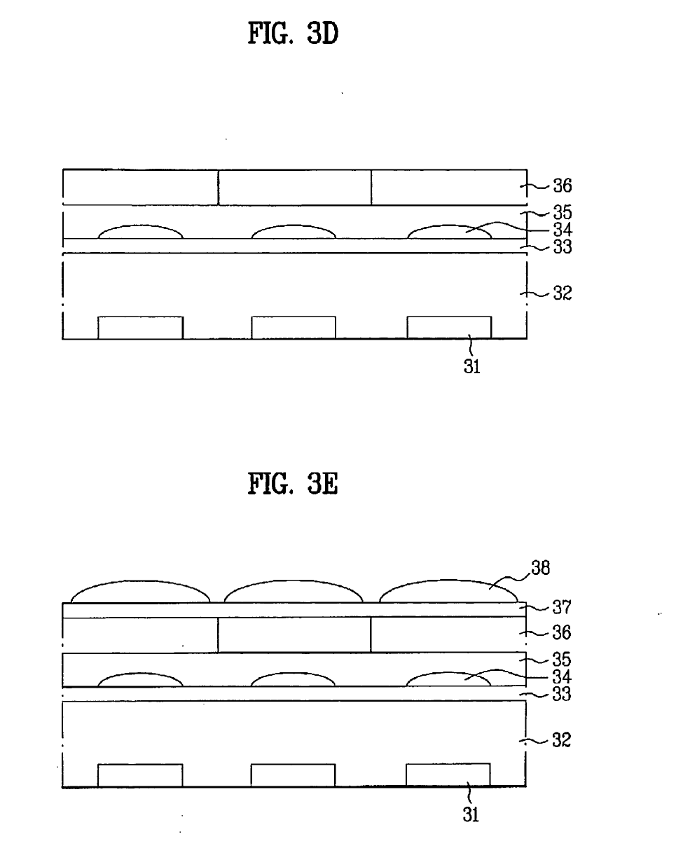

FIGS. 3A-3E show a method of fabricating a CMOS image sensor according to the present invention.

Referring to FIG. 3A, at least one photodiode 31 is formed on a semiconductor substrate to generate an electric charge according to the intensity of radiation of an incident light. An insulating interlayer 32 is formed on the semiconductor substrate including the at least one photodiode 31. The insulating interlayer 32 can include a plurality of layers. In particular, after an optical shielding layer has been formed on the semiconductor substrate including the at least one photodiode 31 to prevent the incident light from entering an area except the at least one photodiode 31, the insulating interlayer 32 is formed on the optical shielding layer. Subsequently, an oxide layer and a nitride layer sequentially are stacked on the insulating interlayer 32 to form a protective layer 33 protecting a device from moisture and scratches.

Referring to FIG. 3B, an oxide layer of resist or SiON is formed on the protective layer 33 to form a first microlens material layer. The first microlens material layer is selectively patterned by exposure and development to form at least one first microlens pattern corresponding to the at least one photodiode 33. Reflowing is carried out on the at least one first microlens pattern to form at least one first microlens 34 having a hemispherical shape.

Referring to FIG. 3C, a first planarizing layer 35 is formed over the substrate including the at least one first microlens 34.

Referring to FIG. 3D, a dyeable resist is coated on the first planarizing layer 35. The dyeable resist is then patterned to form at least one color filter layer 36 that filters light according to different wavelengths.

Referring to FIG. 3E, a second planarizing layer 37 is formed over the substrate including the at least one color filter layer 36. A second microlens material layer is deposited on the second planarizing layer 37. Subsequently, at least one second microlens 38 is formed by patterning the second microlens material layer selectively and by performing reflowing on the patterned layer. The reflowing can be carried out using a hot plate or furnace. Thus, a curvature of the second microlens is varied according to a contracting-heating method. A condensing efficiency depends on the curvature. Subsequently, ultraviolet rays are applied to the second microlens 38 to harden the second microlens 38. By applying the ultraviolet rays to the second microlens 38, an optimal curvature radius of the second microlens 38 is maintained.

The first microlens 34 is formed of a material having a refractive index different from that of the second microlens 38. The refractive index of the second microlens 38 is greater than that of the first microlens 34. Optionally, the first and second microlens 34 and 38 may be formed using oxide and photoresist, respectively. Alternatively, the first and second microlens 34 and 38 can be formed of oxide layers differing from each other in a refractive index. Alternatively, the first and second microlens 34 and 38 can be formed of photoresists differing from each other in a refractive index.

By adopting the CMOS image sensor and fabricating method thereof according to the present invention, uniformity of the light incident on the photodiode can be enhanced. That is, by forming the protective layer, first microlens, first planarizing layer, color filter layer, second planarizing layer and second microlens prior to forming the color filter layer, uniformity of the light incident on the photodiode can be enhanced. Due to the lower variation in the incident light according to a thickness of each layer between the photodiode and the microlens, cell uniformity can also be enhanced. In addition, by maximizing the light transmission efficiency of the light incident on the photodiode by forming the dual microlens structure, the performance of the image sensor can be enhanced.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A CMOS image sensor, comprising:
a plurality of photodiodes on a semiconductor substrate to be uniformly spaced apart from each other;
an insulating interlayer on the semiconductor substrate including the photodiodes;
a protective layer on the insulating interlayer;
a plurality of first microlenses on the protective layer to correspond to the plurality of photodiodes, respectively;
a first planarizing layer over the substrate including the first microlenses;
a color filter layer on the first planarizing layer;
a second planarizing layer over the substrate including the color filter layer; and
a plurality of second microlenses on the second planarizing layer to correspond to the plurality of first microlenses, respectively.

2. The CMOS image sensor of claim 1, wherein a refractive index of the first microlens is different from that of the second microlens.

3. The CMOS image sensor of claim 1, wherein a refractive index of the first microlens is smaller than that of the second microlens.

4. The CMOS image sensor of claim 1, wherein the first microlens is formed of photoresist and wherein the second microlens is formed of SiON.

5. The CMOS image sensor of claim 1, wherein the protective layer comprises an oxide layer and a nitride layer stacked on the oxide layer.

6. The CMOS image sensor of claim 1, wherein the second microlens is configured to be wider than the first microlens and to be overlapped with the first microlens.

7. A method of fabricating a CMOS image sensor, comprising:
forming a plurality of photodiodes on a semiconductor substrate;
forming an insulating interlayer on the semiconductor substrate including the photodiodes;
forming a protective layer on the insulating interlayer;
forming a plurality of first microlenses on the protective layer to correspond to the plurality of photodiodes, respectively;
forming a first planarizing layer over the substrate including the first microlenses;
forming a color filter layer on the first planarizing layer;
forming a second planarizing layer over the substrate including the color filter layer; and
forming a plurality of second microlenses on the second planarizing layer to correspond to the plurality of first microlenses, respectively.

8. The method of claim 7, further comprising the step of hardening the second microlenses by applying ultraviolet rays thereto.

9. The method of claim 7, wherein refractive index of the first microlens is different from that of the second microlens.

10. The method of claim 7, wherein refractive index of the first microlens is smaller than that of the second microlens.
